(19) United States
(12) Patent Application Publication
(10) Pub. No.: US 2007/0165375 A1
(43) Pub. Date: Jul. 19, 2007

(54) Cooling system for a switchgear cabinet

(76) Inventors: Michael Nicolai, Rabenau (DE); Martin Dorrich, Sinn (DE)

Correspondence Address: PAULEY PETERSEN & ERICKSON, 2800 WEST HIGGINS ROAD, SUITE 365, HOFFMAN ESTATES, IL, 60195, US

(21) Appl. No.: 10/543,586

(22) PCT Filed: Jun. 9, 2004
(86) PCT No.: PCT/EP04/06233

§ 371 Date: Jul. 27, 2005

(30) Foreign Application Priority Data
Jun. 13, 2003 (DE) 10326803.0

(51) Int. Cl. H05K 7/20

(52) U.S. Cl. 361/688

(57) ABSTRACT

A cooling system for cooling a switchgear cabinet including, in the interior thereof, heat generating built-in components situated one above the other and to which individual heat sinks are assigned and included in a coolant circuit via a flow line and a return line. The heat sinks are connected to the flow line and to the return line via individual unit supply lines and are supplied with coolant. The coolant circuit is closed via the coolant exit side of the air/water heat exchanger. The air/water heat exchanger is arranged in the bottom area of the switchgear cabinet, and is coupled, via air entry side by an air entry opening of the switchgear cabinet bottom and of an air outlet opening of a double bottom of a setting-up bottom of the switchgear cabinet, to a central air-conditioning device, which supplies the double bottom with cool air. A pump and an expansion tank are included in the closed coolant circuit. This enables, with a simple design and simplified assembly, optimal cooling of built-in components situated one above the other to generate high levels of heat and which have a high packing density.

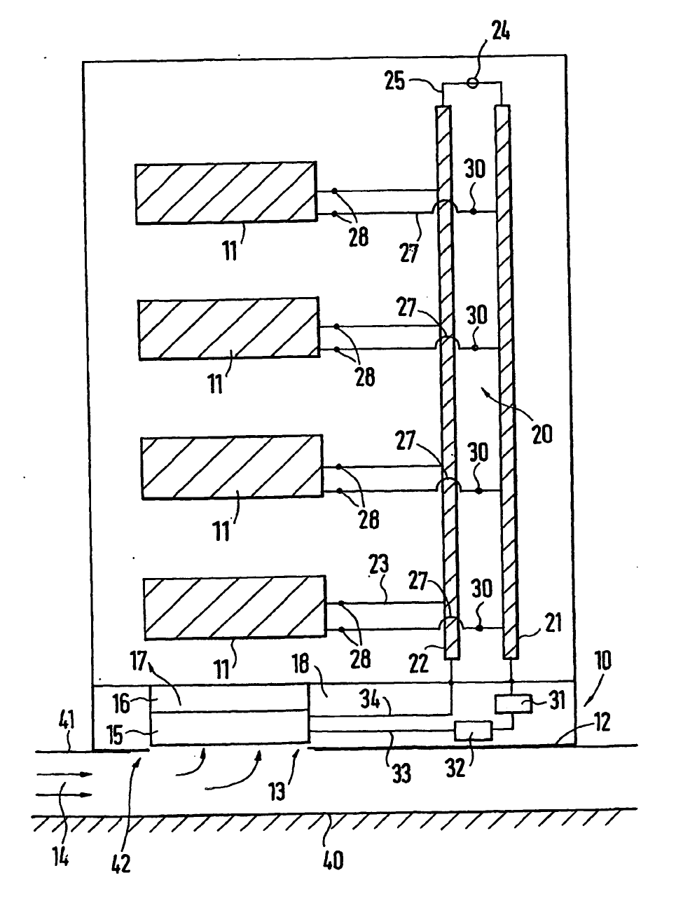

### BACKGROUND OF THE INVENTION

1. Field of the Invention

This invention relates to a cooling system for cooling a switchgear cabinet containing heat-generating built-in devices in its interior, which are arranged on top of each other and to which individual cooling bodies are assigned, which are integrated into a coolant circuit via a feed line and a return line, wherein the cooling bodies are connected via individual device supply lines with the feed line and the return line and are supplied with coolant, and wherein the coolant circuit is closed via the coolant outlet side of an air/water heat exchanger.

2. Discussion of Related Art

A cooling system for cooling a switchgear cabinet is taught by German Patent Reference DE 101 12 389 A1. In this cooling system the cooling bodies are plate-shaped receiver-heat exchangers and are arranged in the intermediate slits between the built-in devices. The large air/water heat exchanger is arranged outside the switchgear cabinet and, as a dispenser-heat exchanger, must be connected with the components of the cooling system in the interior of the switchgear cabinet. The dispenser-heat exchanger is only cooled by the outside air around the switchgear cabinet and thus has a limited effectiveness as a heat exchanger. Also, the construction of the switchgear cabinet with the cooling system is complicated and expensive.

An arrangement for cooling a switchgear cabinet with heat-generating built-in devices arranged on top of each other in the interior is taught by German Patent Reference DE 696 17 089 T2. The built-in devices are cooled by a cooling air flow, which is generated in a central cooling air installation and is supplied to a hollow space between the double bottom of the placement space for the switchgear cabinet. In this case the cooling air is introduced via the bottom of the switchgear cabinet and flows upward through the remaining air channels between the built-in devices and the switchgear cabinet housing and can exit through air outlets in the switchgear cabinet top to the placement space for the switchgear cabinet. Although the cooling air supplied to the interior of the switchgear cabinet can be selected to be colder than the air in the cabinet, the degree of efficiency of the cooling system leaves something to be desired. This even more so, since compact built-in devices providing a considerably greater heat generation are housed more densely packed in the interior of the switchgear cabinet.

### SUMMARY OF THE INVENTION

It is one object of this invention to provide a cooling system of the type mentioned above but which makes possible an improved cooling output in connection with densely packed built-in devices of great heat output in particular, without making more difficult placement of the structure of the switchgear cabinet.

In accordance with this invention, this object is achieved with an air/water heat exchanger arranged in the bottom area of the switchgear cabinet and coupled by its air input side via an air inlet opening of the switchgear cabinet bottom and an air outlet opening of a double bottom of a switchgear placement bottom with a central air-conditioning installation, which supplies the double bottom with cold air. A pump and an expansion vessel are included in the closed coolant circuit.

With this design the higher cooling output of the central air-conditioning installation is used, wherein the switchgear cabinet with the components of the cooling system only needs to be coupled in the form of a structural unit with the double bottom conducting the cold air, which is very easily possible. Also, a closed coolant circuit is optimized in the switchgear cabinet, which increases efficiency and brings advantages, even with dense packing and with high heat generation of the built-in devices. The cooling bodies can be integrated into the built-in devices which are arranged densely stacked on top of each other, or the built-in devices themselves can be embodied as cooling bodies.

The coupling of the structural switchgear cabinet unit with the central air-conditioning installation is simply achieved because the double bottom has air outlet openings closed off by cover plates, which can be removed together with the built-in components of the cooling system at the location of a switchgear cabinet.

The cold air from the central air-conditioning installation can be optimally used for cooling the built-in devices housed in the switchgear cabinet interior because a fan is arranged downstream of the air/water heat exchanger, which conducts the cold air to the interior of the switchgear cabinet after the air has flowed through the air/water heat exchanger. During this, in the upper area of the switchgear cabinet the cold air supplied to the interior of the switchgear cabinet can be specifically exhausted into the space of the switchgear cabinet, which results in a better use of the space air-conditioning installation.

The closed coolant circuit is preferably filled with water, which is kept flowing because the pump and the expansion vessel are inserted between the air/water heat exchanger and the feed line.

Considered from the structural design viewpoint, in one embodiment the air/water heat exchanger, the fan, the pump and the expansion vessel are housed in a partitioned space in the switchgear cabinet, and this embodiment of the cooling system hardly interferes with the installation of the built-in devices in the switchgear cabinet. This embodiment can be further simplified if the partitioned space with the installed components is a separate structural component, on which the switchgear cabinet can be installed and can be connected via the feed line and the return line with the associated connectors of the structural component.

The space required for the feed line, the return line and the individual device supply lines can be minimized if the feed line and the return line are conducted over the entire height of the interior of the switchgear cabinet in a vertical conduit formed between the cabinet wall and the built-in devices and are connected with each other in an upper area of the interior via a connecting line with a ventilating unit. The layout of the feed line and the return line can be further simplified and have a lower assembly cost if in connection with a switchgear cabinet with a rack and paneling elements, the feed line and the return line are conducted in a receptacle or a hollow space over vertical frame legs of the rack.

### BRIEF DESCRIPTION OF THE DRAWING

This invention is explained in view of an exemplary embodiment represented in the drawing, in a schematic view.

### DESCRIPTION OF PREFERRED EMBODIMENTS

In the drawing, the double bottom of the switchgear cabinet placement space is identified by the reference numerals 40 and 41, to which is provided the cold air 14 from the central air-conditioning installation, not shown. The part 41 of the double bottom is used as the placement surface for the switchgear cabinet 10. It is possible here to remove cover plates for forming an air outlet opening 42. An air inlet opening 13 for the cold air 14 is provided in the bottom 12 of the switchgear cabinet 10. Thus, the air inlet opening 13 of the switchgear cabinet 10 only needs to be placed so that it is aligned with the air outlet opening 42 of the bottom part 41.

After passing through the air inlet opening 13, the cold air 14 flows through the air/water heat exchanger 15 and cools the coolant, preferably water, flowing through the air/water heat exchanger 15. With its coolant outlet side, the air/water heat exchanger 15 is included in a closed and water-filled coolant circuit 20, which is closed via the supply lines 33 and 34 and the feed line 21 and the return lines 22 and the connected cooling bodies 11. In this case, the cooling bodies 11 of the built-in devices arranged on top of each other are connected with the feed line 21 and the return line via device supply lines 23 and 27. The connections can be provided by releasable couplings 28 and 30, which form a seal after the release. A pump 31 and an expansion vessel 32 are installed in the feed line 21 and the supply line 33, which maintain the flow of the coolant water in the coolant circuit 20 independently of the pressure and the temperature of the coolant. In this case, the feed line 21 can be connected with the return line 22 via a connecting line 25 with the exhaust device 24 in the upper area of the switchgear cabinet.

The cooling bodies 11 are individually assigned to the built-in devices and can be integrated into them in a heat-conducting manner and provide cooling. The housings of the built-in devices can be embodied as cooling bodies and the coolant can flow through them.

Following the passage through the air/water heat exchanger 15, the cold air 14 from the central air-conditioning installation can be conducted by a fan 16 to the interior 17 of the switchgear cabinet 10. In the interior 17, the warmed, yet still cold air rises upward in the channels remaining between the built-in devices and the switchgear cabinet, and further participates in the cooling of the built-in devices. Finally, the rising air can flow via air outlets of the switchgear cabinet 10 into the air in the vicinity of or near the switchgear cabinet 10. The air/water heat exchanger 15, the fan 16, the pump 31 and the expansion vessel 32 can be housed in a space 18 partitioned from the switchgear cabinet interior 17, and thus do not interfere with the installation of the built-in devices with their cooling bodies 11.

The space 18 can, however, also be formed by a separate structural unit and receive these components of the cooling installation. This structural unit is coupled in the same way with the central air-conditioning installation via the double bottom 40,41. The structural unit can be used as a base for the switchgear cabinet 10, wherein it is only necessary to couple the switchgear cabinet 10 placed on it, the feed line 21 and the return line 22 with the air/water heat exchanger 15, and the fan 16 with the switchgear cabinet interior 17. In addition, the separate structural unit can be mechanically connected with the switchgear cabinet 10.

1. A cooling system for cooling a switchgear cabinet (10) containing heat-generating built-in devices in an interior, which are arranged on top of each other and to which individual cooling bodies (11) are assigned, which are integrated into a coolant circuit (20) via a feed line (21) and a return line (22), wherein the cooling bodies (11) are connected via individual device supply lines (30, 23) with the feed line (21) and the return line (22) and are supplied with coolant, and wherein the coolant circuit (20) is closed via the coolant outlet side of an air/water heat exchanger (15), the improvement comprising:
the air/water heat exchanger (15) arranged in a bottom area (18) of the switchgear cabinet (10) and coupled by an air input side via an air inlet opening (13) of a switchgear cabinet bottom (12) and an air outlet opening (42) of a double bottom (40, 41) of a switchgear placement bottom with a central air-conditioning installation which supplies the double bottom (40, 41) with cold air, and a pump (31) and an expansion vessel (32) included in the closed coolant circuit (20).

2. The cooling system in accordance with claim 1, wherein the cooling bodies (11) are integrated into the built-in devices which are densely stacked on top of each other.

3. The cooling system in accordance with claim 1, wherein the built-in devices are cooling bodies (11).

4. The cooling system in accordance with claim 3, wherein the double bottom (40, 41) has the air outlet opening (42) closed off by of cover plates which can be removed together with the built-in devices of the cooling system at a location of the switchgear cabinet (10).

5. The cooling system in accordance with claim 4, wherein a fan (16) is arranged downstream of the air/water heat exchanger (15), and conducts a cold air (14) to the interior (17) of the switchgear cabinet (10) after flowing through the air/water heat exchanger (15).

6. The cooling system in accordance with claim 5, wherein that in one of an upper area and a rear area of the switchgear cabinet (10) the cold air (14) supplied to the interior (17) of the switchgear cabinet (10) is exhausted into a placement space of the switchgear cabinet (10).

7. The cooling system in accordance with claim 6, wherein the pump (31) and the expansion vessel (32) are inserted between the air/water heat exchanger (15) and the feed line (21).

8. The cooling system in accordance with claim 7, wherein the air/water heat exchanger (15), the fan (16), the pump (31) and the expansion vessel (32) are housed in a partitioned space (18) of the switchgear cabinet (10).

9. The cooling system in accordance with claim 8, wherein the partitioned space (18) with the installed components is a separate structural component on which the switchgear cabinet (10) is installed and connected via the feed line (21) and the return line (22) with associated connectors of the structural component.

10. The cooling system in accordance with claim 9, wherein the feed line (21) and the return line (22) are conducted over the a height of the switchgear cabinet interior (17) in a vertical conduit formed between a cabinet wall and the built-in devices, and are connected with each other in an upper area of the interior via a connecting line (25) with a ventilating unit (24).

11. The cooling system in accordance with claim 10, wherein in connection with the switchgear cabinet (10) with a rack and paneling elements, the feed line (21) and the return line (22) are conducted in one of a receptacle and a hollow space over vertical frame legs of the rack.

12. The cooling system in accordance with claim 1, wherein the double bottom (40,41) has the air outlet opening (42) closed off by cover plates which can be removed together with the built-in devices of the cooling system at a location of the switchgear cabinet (10).

13. The cooling system in accordance with claim 1, wherein a fan (16) is arranged downstream of the air/water heat exchanger (15) and conducts a cold air (14) to the interior (17) of the switchgear cabinet (10) after flowing through the air/water heat exchanger (15).

14. The cooling system in accordance with claim 13, wherein in one of an upper area and a rear area of the switchgear cabinet (10) the cold air (14) supplied to the interior (17) of the switchgear cabinet (10) is exhausted into a placement space of the switchgear cabinet (10).

15. The cooling system in accordance with claim 1, wherein the pump (31) and the expansion vessel (32) are inserted between the air/water heat exchanger (15) and the feed line (21).

16. The cooling system in accordance with claim 1, wherein the air/water heat exchanger (15), a fan (16), the pump (31) and the expansion vessel (32) are housed in a partitioned space (18) of the switchgear cabinet (10).

17. The cooling system in accordance with claim 16, wherein the partitioned space (18) with the installed components is a separate structural component on which the switchgear cabinet (10) is installed and connected via the feed line (21) and the return line (22) with associated connectors of the structural component.

18. The cooling system in accordance with claim 1, wherein the feed line (21) and the return line (22) are conducted over a height of the switchgear cabinet interior (17) in a vertical conduit formed between a cabinet wall and the built-in devices, and are connected with each other in an upper area of the interior via a connecting line (25) with a ventilating unit (24).

19. The cooling system in accordance with claim 1, wherein in connection with the switchgear cabinet (10) with a rack and paneling elements, the feed line (21) and the return line (22) are conducted in one of a receptacle and a hollow space over vertical frame legs of the rack.
